(19) United States
(12) Patent Application Publication
(10) Pub. No.: US 2026/0037147 A1
(43) Pub. Date: Feb. 5, 2026

(54) OPERATING METHOD OF PAGE BUFFER FOR READ OPERATION OF SEMICONDUCTOR DEVICE

(71) Applicant: SK hynix Inc., Icheon-si Gyeonggi-do (KR)

(72) Inventor: Jae Woong KIM, Icheon-si Gyeonggi-do (KR)

(73) Assignee: SK hynix Inc., Icheon-si Gyeonggi-do (KR)

(21) Appl. No.: 18/958,602

(22) Filed: Nov. 25, 2024

(30) Foreign Application Priority Data
Aug. 5, 2024 (KR) 10-2024-0103585

(51) Int. Cl. G06F 3/06

(52) U.S. Cl. CPC G06F 3/0619; G06F 3/0656; G06F 3/0673

(57) ABSTRACT

An operating method of a semiconductor device includes receiving a read command and sensing a memory cell adjacent to a target memory cell of the read command. The method also includes sensing the target memory cell at a first sensing time and sensing the target memory cell at a second sensing timing. The method further includes outputting, as data, a value sensed at the first sensing time or a value sensed at the second sensing time on the basis of a sensing value of the memory cell adjacent to the target memory cell.

### CROSS-REFERENCE TO RELATED APPLICATION

The present application claims priority under 35 U.S.C. § 119 (a) to Korean Patent Application No. 10-2024-0103585 filed on Aug. 5, 2024, which application is incorporated herein by reference in its entirety.

### BACKGROUND

### 1. Technical Field

Embodiments of the present disclosure relate to integrated circuit technology, and more particularly, to an operating method of a page buffer for a read operation of a semiconductor device.

### 2. Related Art

With the miniaturization, low power consumption, high performance, diversification, and the like of electronic devices, there is a demand for semiconductor devices capable of storing information in various electronic devices, such as, computers and portable communication devices. Semiconductor devices may be roughly classified as volatile memory devices or nonvolatile memory devices. A volatile memory device has a high data processing speed but has a disadvantage in that power needs to be continuously supplied to retain stored data. A nonvolatile memory device does not need to be continuously supplied with power to retain stored data but has a disadvantage in that its data processing speed is low.

A nonvolatile memory device performs a program operation to store data and performs a read operation for outputting stored data. As the nonvolatile memory device is reduced in size, the gap between memory cells becomes narrower, which may cause errors when adjacent memory cells are affected during a program or read operation of a targeted memory cell.

Research is being conducted to ensure that a normal program or read operation is performed as the nonvolatile memory device is reduced in size.

### SUMMARY

In an embodiment of the present disclosure, an operating method of a semiconductor device may include: receiving a read command; sensing a memory cell adjacent to a target memory cell of the read command; sensing the target memory cell at a first sensing time; sensing the target memory cell at a second sensing time; and outputting, as data, a value sensed at the first sensing time or a value sensed at the second sensing time on the basis of a sensing value of the memory cell adjacent to the target memory cell.

In an embodiment of the present disclosure, an operating method of a page buffer may include: connecting a sensing node of the page buffer to a bit line during a read operation; sensing the sensing node by driving a first word line and storing a first sensed value in a first latch; sensing the sensing node at a first time by driving a second word line with a first voltage and storing a second sensed value in a second latch; sensing the sensing node at a second time after the first time by driving the second word line with a second voltage different from the first voltage and storing a third sensed value in a third latch; and outputting the second sensed value stored in the second latch or the third sensed value stored in the third latch as data on the basis of the first sensed value stored in the first latch.

In an embodiment of the present disclosure, a page buffer may include: a first latch that senses a first voltage value of a sensing node formed by a first word line; a second latch that senses a second voltage value of the sensing node formed by a second word line adjacent to the first word line; and a third latch that senses a third voltage value of the sensing node formed by the second word line, wherein the third voltage value is sensed at a different time from when the second voltage value is sensed.

### BRIEF DESCRIPTION OF THE DRAWINGS

FIG. 1 is a diagram illustrating a configuration of a semiconductor device in accordance with an embodiment of the present disclosure.

FIGS. 2 and 3 are diagrams illustrating a structure of a memory cell array included in a semiconductor device in accordance with an embodiment of the present disclosure.

FIG. 4 is a diagram for describing a read operation of a semiconductor device in accordance with an embodiment of the present disclosure.

FIG. 5 is a diagram illustrating a configuration of a page buffer included in a semiconductor device in accordance with an embodiment of the present disclosure.

FIG. 6 is a timing diagram for describing an operation of a page buffer included in a semiconductor device in accordance with an embodiment of the present disclosure.

FIG. 7 is a flowchart for describing an operating method of a page buffer included in a semiconductor device in accordance with an embodiment of the present disclosure.

### DETAILED DESCRIPTION

Various embodiments are directed to an operating method of a page buffer for a read operation of a semiconductor device capable of performing a normal read operation while increasing a read operation speed.

Some embodiments have an effect of improving the reliability of a semiconductor device by increasing a read speed and preventing errors in the read operation.

Hereafter, example embodiments in accordance with the technical spirit of the present disclosure are described with reference to the accompanying drawings.

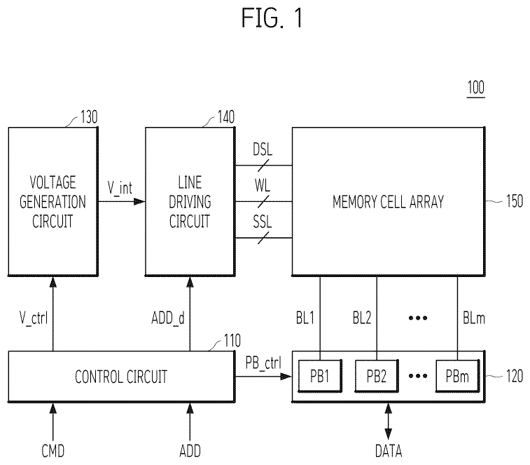

FIG. 1 is a diagram illustrating a configuration of a semiconductor device 100 in accordance with an embodiment of the present disclosure.

Referring to FIG. 1, the semiconductor device 100 includes a control circuit 110, a page buffer group 120, a voltage generation circuit 130, a line driving circuit 140, and a memory cell array 150.

In an embodiment, the control circuit 110 controls the page buffer group 120, the voltage generation circuit 130, the line driving circuit 140, and the memory cell array 150 on the basis of a command signal CMD and an address signal ADD. For example, the control circuit 110 controls page buffer group 120, the voltage generation circuit 130, and the line driving circuit 140 according to the command signal CMD and the address signal ADD to program data DATA to the memory cell array 150 or output the data DATA stored in the memory cell array 150.

In an embodiment, the control circuit 110 generates a page buffer signal PB_ctrl on the basis of the command signal CMD and the address signal ADD, and provides the page buffer control signal PB_ctrl to the page buffer group 120.

In an embodiment, the control circuit 110 generates a voltage control signal V_ctrl on the basis of the command signal CMD, and provides the voltage control signal V_ctrl to the voltage generation circuit 130.

In an embodiment, the control circuit 110 generates a driving address signal ADD_d on the basis of the command signal CMD and the address signal ADD, and provides the driving address signal ADD_d to the line driving circuit 140.

In an embodiment, the page buffer group 120 includes a plurality of page buffers PB1, PB2, . . . , PBm (m is a natural number). The plurality of page buffers PB1, PB2, . . . , PBm are connected to a plurality of bit lines BL1, BL2, . . . , BLm (m is a natural number), respectively. Each of the plurality of page buffers PB1, PB2, . . . , PBm senses a data value, which is stored in a memory cell, through a bit line on the basis of a page buffer control signal PB_ctrl during a read operation, and outputs the sensed value as data DATA.

In a first embodiment, during a read operation, each of the plurality of page buffers PB1, PB2, . . . , PBm selects one of the sensing values of a target memory cell, which are sensed with different levels of read voltages, on the basis of a sensing value of a memory cell adjacent to the target memory cell of the read operation, and outputs the selected sensing value as the data DATA.

In a second embodiment, during a read operation, each of the plurality of page buffers PB1, PB2, . . . , PBm selects one of the sensing values of a target memory cell, which are sensed at different sensing times, on the basis of a sensing value of a memory cell adjacent to the target memory cell of the read operation, and outputs the selected sensing value as the data DATA.

In an embodiment, the voltage generation circuit 130 generates internal voltages V_int having various voltage levels on the basis of the voltage control signal V_ctrl, and provides the internal voltages V_int to the line driving circuit 140. The internal voltages V_int include voltages having different voltage levels, such as, a read voltage, a program voltage, and a pass voltage.

In an embodiment, the line driving circuit 140 drives drain select lines DSL, word lines WL, and source select lines SSL at the voltage level of the internal voltages V_int on the basis of the driving address signal ADD_d. For example, the line driving circuit 140 drives at least one of the drain select lines DSL by a pass voltage on the basis of the driving address signal ADD_d. The line driving circuit 140 also drives at least one of the source select lines SSL by a pass voltage on the basis of the driving address signal ADD_d. In addition, the line driving circuit 140 drives at least one of the word lines WL by a read voltage or a program voltage and drives the remaining lines by a pass voltage on the basis of the driving address signal ADD_d.

In an embodiment, the memory cell array 150 includes a plurality of memory strings selected by driving the drain select lines DSL and the source select lines SSL, and each of the plurality of memory strings includes a plurality of memory cells. Each of the plurality of memory cells is programmed by driving the plurality of bit lines BL1, BL2, . . . , BLm and the word lines WL, and stored data is also output.

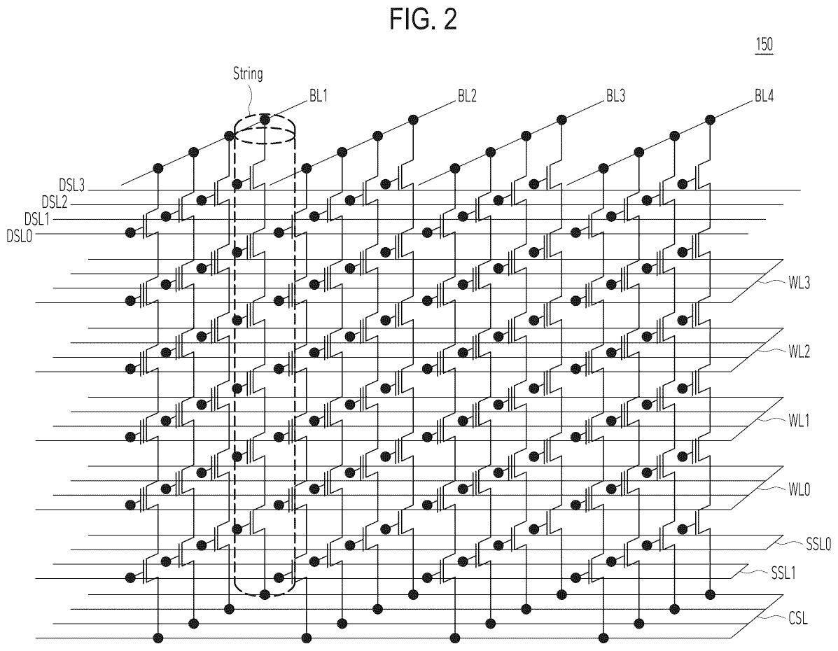

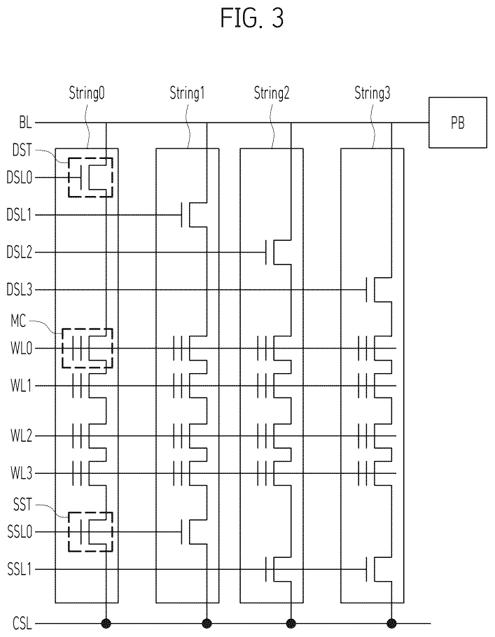

FIGS. 2 and 3 are diagrams illustrating a structure of a memory cell array 150 included in a semiconductor device in accordance with an embodiment of the present disclosure.

Referring to FIGS. 2 and 3, the memory cell array 150 includes a plurality of memory strings String connected between a plurality of bit lines BL1, BL2, BL3, and BL4 and a source line CSL.

FIG. 2 illustrates a structure in which 16 memory strings are connected between the four bit lines BL1, BL2, BL3, and BL4 and the source line CSL. Other embodiments may include fewer or a greater number of memory strings. The embodiment of FIG. 2 is described as a structure in which four drain select lines DSL0, DSL1, DSL2, and DSL3, four word lines WL0, WL1, WL2, and WL3, and two source select lines SSL0 and SSL1 are connected to the memory strings; however, the present disclosure is not limited thereto.

Referring to FIG. 2, four memory strings String are connected between a first bit line BL1 and the source line CSL. Four memory strings String are connected between a second bit line BL2 and the source line CSL. Four memory strings String are connected between a third bit line BL3 and the source line CSL. Four memory strings String are connected between a fourth bit line BL4 and the source line CSL.

In an embodiment, in each of the 16 memory strings String connected between the first to fourth bit lines BL1, BL2, BL3, and BL4 and the source line CSL, at least one transistor connected to each of first to fourth drain select lines DSL0, DSL1, DSL2, and DSL3, a plurality of transistors respectively connected to first to fourth word lines WL0, WL1, WL2, and WL3, and at least one transistor connected to each of first and second source select lines SSL0 and SSL1 are connected in series. In such a case, the serially connected transistors constituting the memory string String are named as follows. The transistors connected to the first to fourth drain select lines DSL0, DSL1, DSL2, and DSL3 are referred to as drain select transistors. The plurality of transistors connected to the first to fourth word lines WL0, WL1, WL2, and WL3 are referred to as cell transistors. The transistors connected to the first and second source select lines SSL0 and SSL1 are referred to as source select transistors.

In an embodiment, the memory cell array 150 configured in this way operates as follows.

At least one memory string among the 16 memory strings is selected by at least one drain select line driven among the first to fourth drain select lines DSL0, DSL1, DSL2, and DSL3 and at least one source select line driven among the first and second source select lines SSL0 and SSL1. For example, when the first drain select line DSL0 and the first source select line SSL0 are driven, one memory string connected to the first bit line BL1, one memory string connected to the second bit line BL2, one memory string connected to the third bit line BL3, and one memory string connected to the fourth bit line BL4 are selected. In addition, at least one of cell transistors included in each of the selected memory strings String is selected by the first to fourth word lines WL0, WL1, WL2, and WL3. The selected cell transistors are programmed or read.

FIG. 3 illustrates four memory strings String0, String1, String2, and String3 connected between one bit line BL and a source line CSL in the memory cell array 150 illustrated in FIG. 2. In such a case, the four memory strings String0, String1, String2, and String3 include a first memory string String0, a second memory string String1, a third memory string String2, and a fourth memory string String3.

Referring to FIG. 3, each of the first to fourth memory strings String0, String1, String2, and String3 is electrically connected between one bit line BL and the source line CSL. Each of the first to fourth memory strings String0, String1, String2, and String3 includes at least one drain select transistor DST, a plurality of cell transistors MC, and at least one source select transistor SST. The at least one drain select transistor DST, the plurality of cell transistors MC, and the at least one source select transistor SST included in each of the first to fourth memory strings String0, String1, String2, and String3 are connected in series.

For example, the first memory string String0 includes a drain select transistor DST, a plurality of cell transistors MC, and a source select transistor SST. The drain select transistor DST, the plurality of cell transistors MC, and the source select transistor SST connected in series are connected between the bit line BL and the source line CSL. The drain select transistor DST of the first memory string String0 is connected to the first drain select line DSL0. The plurality of cell transistors MC of the first memory string String0 are connected to the plurality of word lines WL0, WL1, WL2, and WL3, respectively. The source select transistor SST of the first memory string String0 is connected to the first source select line SSL0.

In an embodiment, the second memory string String1 includes a drain select transistor, a plurality of cell transistors, and a source select transistor. The drain select transistor, the plurality of cell transistors, and the source select transistor connected in series are connected between the bit line BL and the source line CSL. The drain select transistor of the second memory string String1 is connected to the second drain select line DSL1. The plurality of cell transistors of the second memory string String1 are connected to the plurality of word lines WL0, WL1, WL2, and WL3, respectively. The source select transistor of the second memory string String1 is connected to the first source select line SSL0.

In an embodiment, the third memory string String2 includes a drain select transistor, a plurality of cell transistors, and a source select transistor. The drain select transistor, the plurality of cell transistors, and the source select transistor connected in series are connected between the bit line BL and the source line CSL. The drain select transistor of the third memory string String2 is connected to the third drain select line DSL2. The plurality of cell transistors of the third memory string String2 are connected to the plurality of word lines WL0, WL1, WL2, and WL3, respectively. The source select transistor of the third memory string String2 is connected to the second source select line SSL1.

In an embodiment, the fourth memory string String3 includes a drain select transistor, a plurality of cell transistors, and a source select transistor. The drain select transistor, the plurality of cell transistors, and the source select transistor connected in series are connected between the bit line BL and the source line CSL. The drain select transistor of the fourth memory string String3 is connected to the fourth drain select line DSL3. The plurality of cell transistors of the fourth memory string String3 are connected to the plurality of word lines WL0, WL1, WL2, and WL3, respectively. The source select transistor of the fourth memory string String3 is connected to the second source select line SSL1.

In an embodiment, one bit line BL to which the first to fourth memory strings String0, String1, String2, and String3 are connected is connected to one page buffer PB.

Accordingly, one memory string among the first to fourth memory strings String0, String1, String2, and String3 is selected by the first to fourth drain select lines DSL0, DSL1, DSL2, and DSL3 and the first and second source select lines SSL0 and SSL1. In addition, one of a plurality of memory cells included in a memory string selected by the plurality of word lines WL0, WL1, WL2, and WL3 is selected. The selected memory cell is connected to the page buffer PB through the bit line BL. Thus, the page buffer PB senses the selected memory cell.

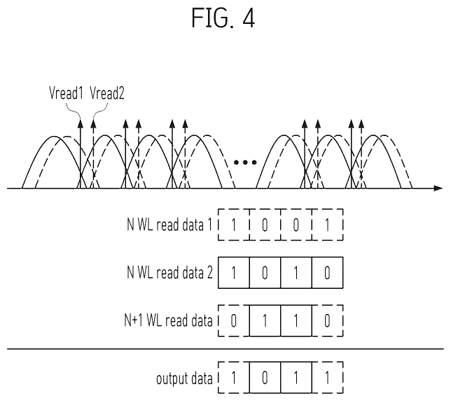

FIG. 4 is a diagram for describing a read operation of a semiconductor device in accordance with an embodiment of the present disclosure.

Referring to FIG. 4, to prevent a read error due to impedance interference, the read operation of the semiconductor device in accordance with an embodiment of the present disclosure senses a target memory cell with different levels of first and second read voltages Vread1 and Vread2, selects one of the sensing values of the target memory cell on the basis of sensing values of a memory cell adjacent to the target memory cell, and outputs the selected value as data. The target memory cell is a memory cell connected to an Nth word line N WL, and the adjacent memory cell is a memory cell connected to an N+1^{th} word line N+1 WL. The impedance interference is a phenomenon in which a threshold voltage of the target memory cell changes according to a change in a threshold voltage of the adjacent memory cell. In particular, as illustrated in FIG. 3, the impedance interference described in the semiconductor device in accordance with an embodiment of the present disclosure means a change in a threshold voltage between memory cells connected to each of adjacent word lines (for example, WL0 and WL1).

FIG. 4 is an example of a semiconductor device that reads 4 bits of data in one read operation. Accordingly, FIG. 4 illustrates data of memory cells sensed through four bit lines among memory cells connected to a selected word line. It is assumed that a word line connected to a target memory cell of the read operation is the Nth word line N WL, and it is assumed that during a program operation, memory cells of the Nth word line are programmed and then memory cells of the N+1^{th} word line are programmed.

In an embodiment, during the read operation, the Nth word line N WL is driven by the second read voltage Vread2, and the memory cells connected to the Nth word line N WL are connected to four page buffers through four bit lines. The four page buffers sense the memory cells connected to the Nth word line N WL. In such a case, read data N WL read data1 is 1, 0, 0, 1.

Subsequently, the Nth word line N WL is driven by the first read voltage Vread1, and the memory cells connected to the Nth word line N WL are connected to four page buffers through four bit lines. The four page buffers sense the memory cells connected to the Nth word line N WL. In such a case, read data N WL read data2 is 1, 0, 1, 0.

Subsequently, the memory cells connected to the N+1^{th} word line N+1 are connected to four page buffers through four bit lines. In such a case, read data N+1 WL read data is 0, 1, 1, 0.

In an embodiment, the read operation of the semiconductor device in accordance with an embodiment of the present disclosure selects one of the read data N WL read data1 and N WL read data2 by using the first and second read voltages Vread1 and Vread2 according to a data value sensed by driving the N+1^{th} word line N+1 WL, and outputs the selected data as output data.

For example, when the data value sensed by driving the N+1^{th} word line N+1 WL is 0, a corresponding bit of data read using the second read voltage Vread2 is selected and is output as output data. On the other hand, when the data value sensed by driving the N+1^{th} word line N+1 WL is 1, a corresponding bit of data read using the first read voltage Vread1 is selected and is output as output data. Accordingly, in the read operation of FIG. 4 in accordance with an embodiment, the output data is 1, 0, 1, 1.

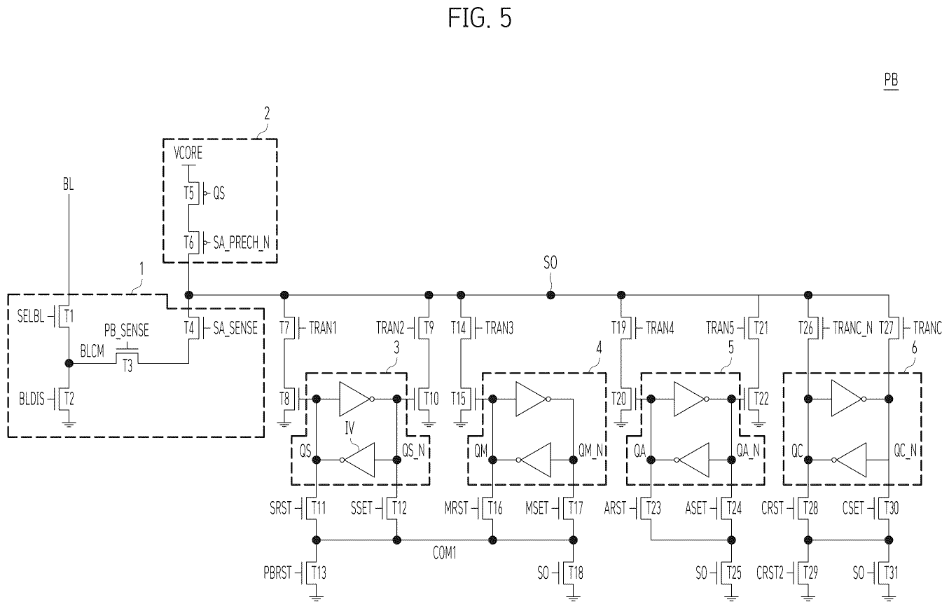

FIG. 5 is a diagram illustrating a configuration of a page buffer PB included in a semiconductor device in accordance with an embodiment of the present disclosure.

Referring to FIG. 5, the page buffer PB includes a connection circuit 1, a precharge circuit 2, and first to fourth latches 3, 4, 5, and 6. The page buffer PB includes a plurality of transistors T7 to T31 capable of controlling the operations of the first to fourth latches 3, 4, 5, and 6. In such a case, the page buffer control signal PB_ctrl of FIG. 1 includes signals for controlling each component of the page buffer PB illustrated in FIG. 5.

In an embodiment, the connection circuit 1 electrically connects or isolates the bit line BL to or from a sensing node SO. The connection circuit 1 includes first to fourth transistors T1, T2, T3, and T4. The first transistor T1 includes a gate that receives a bit line select signal SELBL, and a drain and a source to which the bit line BL and the third transistor T3 are connected, respectively. The second transistor T2 includes a gate that receives a bit line discharge signal BLDIS, a drain to which a node is connected, and a source to which a ground terminal is connected, the first and third transistors T1 and T3 being commonly connected to the node. The third transistor T3 includes a gate that receives a page buffer sensing signal PB_SENSE, and a drain and a source to which the first transistor T1 and the fourth transistor T4 are connected, respectively. The fourth transistor T4 includes a gate that receives a sensing node sensing signal SA_SENSE, and a drain and a source to which the third transistor T3 and the sensing node SO are connected, respectively. In such a case, when the bit line discharge signal BLDIS is enabled in a state in which the bit line select signal SELB is enabled, the connection circuit 1 discharges the bit line BL. In addition, when the bit line select signal SELBL, the page buffer sensing signal PB_SENSE, and the sensing node sensing signal SA_SENSE are all enabled, the connection circuit 1 electrically connects the bit line BL and the sensing node SO through the first transistor T1, the third transistor T3, and the fourth transistor T4.

In an embodiment, the precharge circuit 2 precharges the sensing node SO. The precharge circuit 20 includes fifth and sixth transistors T5 and T6. The fifth transistor T5 includes a gate to which a QS node QS is connected, a source that receives a core voltage VCORE, and a drain to which the sixth transistor T6 is connected. The sixth transistor T6 includes a gate that receives a precharge signal SA_PRECH_N, a source to which the fifth transistor T5 is connected, and a drain to which the sensing node SO is connected. When the QS node QS is at a low level and the precharge signal SA_PRECH_N is enabled, the precharge circuit 2 precharges the sensing node SO by providing the core voltage VCORE to the sensing node SO.

In an embodiment, each of the first to fourth latches 3, 4, 5, and 6 includes two inverters IV. Each of the first to fourth latches 3, 4, 5, and 6 has a structure in which the output of one inverter IV is provided as the input of the other inverter IV, and is implemented such that the input and output of the inverters IV are circulated. In such a case, the first latch 3 includes the QS node QS and a QS_N node QS_N. The second latch 4 includes a QM node QM and a QM_N node QM_N. The third latch 5 includes a QA node QA and a QA_N node QA. The fourth latch 6 includes a QC node QC and a QC_N node QC_N.

In an embodiment, the first and second latches 3 and 4 sense and latch the voltage level of the sensing node SO under the control of the seventh to eighteenth transistors T7, T8, T9, T10, T11, T12, T13, T14, T15, T16, T17, and T18, and transmit the latched value to the sensing node SO. The seventh transistor T7 includes a gate that receives a first transmission signal TRAN1, and a drain and a source to which the sensing node SO and the eighth transistor T8 are connected, respectively. The eighth transistor T8 includes a gate to which the QS node QS is connected, and a drain and a source to which the seventh transistor T7 and the ground terminal are connected, respectively. When the first transmission signal TRAN1 is enabled, the sensing node SO is connected to the ground terminal according to the voltage level of the QS node QS. In such a case, the voltage level of the precharged sensing node SO is changed. The voltage level of the precharged sensing node SO corresponds to a level of a core voltage VCORE and is a high level being a digital level. The level of the sensing node SO having a voltage level changed by the enabled first transmission signal TRAN1 is a low level. The ninth transistor T9 includes a gate that receives a second transmission signal TRAN2, and a drain and a source to which the sensing node SO and the tenth transistor T10 are connected, respectively. The tenth transistor T10 includes a gate to which the QS_N node QS_N is connected, a drain to which the ninth transistor T9 is connected, and a source to which the ground terminal is connected. When the second transmission signal TRAN2 is enabled, the sensing node SO is connected to the ground terminal according to the voltage level of the QS_N node QS_N. In such a case, the voltage level of the precharged sensing node SO is changed. The level of the sensing node SO having a voltage level changed by the enabled second transmission signal TRAN2 is a low level. The eleventh transistor T11 includes a gate that receives a first reset signal SRST, a drain to which the QS node QS is connected, and a source to which a common node COM1 is connected. The twelfth transistor T12 includes a gate that receives a first set signal SSET, a drain to which the QS_N node QS_N is connected, and a source to which the common node COM1 is connected. The thirteenth transistor T13 includes a gate that receives a page buffer reset signal PBRST, a drain to which the common node COM1 is connected, and a source to which the ground terminal is connected. The fourteenth transistor T14 includes a gate that receives a third transmission signal TRAN3, and a drain and a source to which the sensing node SO and a fifteenth transistor T15 are connected, respectively. The fifteenth transistor T15 includes a gate to which the QM node QM is connected, and a drain and a source to which the fourteenth transistor T14 and the ground terminal are connected, respectively. When the third transmission signal TRAN3 is enabled, the sensing node SO is connected to the ground terminal according to the voltage level of the QM node QM. In such a case, the voltage level of the precharged sensing node SO is changed. The sensing node SO having the changed voltage level is at a low level. The sixteenth transistor T16 includes a gate that receives a second reset signal MRST, a drain to which the QM node QM is connected, and a source to which the common node COM1 is connected. The seventeenth transistor T17 includes a gate that receives a second set signal MSET, a drain to which the QM_N node QM_N is connected, and a source to which the common node COM1 is connected. The eighteenth transistor T18 includes a gate to which the sensing node SO is connected, a drain to which the common node COM1 is connected, and a source to which the ground terminal is connected. The first latch 3 is reset when the first reset signal SRST is enabled in a state in which the page buffer reset signal PBRST is enabled. In such a case, the reset first latch 3 is in a state in which the QS node QS is at a low level and the QS_N node QS_N is at a high level. The second latch 4 is reset when the second reset signal MRST is enabled in a state in which the page buffer reset signal PBRST is enabled. The reset second latch 4 is in a state in which the QM node QM is at a low level and the QM_N node QS_N is at a high level.

In an embodiment, the third latch 5 senses and latches the voltage level of the sensing node SO under the control of the nineteenth to twenty-fifth transistors T19, T20, T21, T22, T23, T24, and T25, and transmits the latched value to the sensing node SO. The nineteenth transistor T19 includes a gate that receives a fourth transmission signal TRAN4, and a drain and a source to which the sensing node SO and the twentieth transistor T20 are connected, respectively. The twentieth transistor T20 includes a gate to which the QA node QA is connected, and a drain and a source to which the nineteenth transistor T19 and the ground terminal are connected, respectively. When the fourth transmission signal TRAN4 is enabled, the sensing node SO is connected to the ground terminal according to the voltage level of the QA node QA. In such a case, the voltage level of the precharged sensing node SO is changed. The level of the sensing node SO having a voltage level changed by the enabled fourth transmission signal TRAN4 is a low level. The twenty-first transistor T21 includes a gate that receives a fifth transmission signal TRAN5, and a drain and a source to which the sensing node SO and the twenty-second transistor T22 are connected, respectively. The twenty-second transistor T22 includes a gate to which the QA_N node QA_N is connected, a drain to which the twenty-first transistor T21 is connected, and a source to which the ground terminal is connected. When the fifth transmission signal TRAN5 is enabled, the sensing node SO is connected to the ground terminal according to the voltage level of the QA_N node QA_N. In such a case, the voltage level of the precharged sensing node SO is changed. The level of the sensing node SO having a voltage level changed by the enabled fifth transmission signal TRAN5 is a low level. The twenty-third transistor T23 includes a gate that receives a third reset signal ARST, and a drain to which a QA node QA is connected. The twenty-fourth transistor T24 includes a gate that receives a third set signal ASET, and a drain to which the QA_N node QA_N is connected. The twenty-fifth transistor T25 includes a gate to which the sensing node SO is connected, a drain to which a node is connected, and a source to which the ground terminal is connected, the twenty-third and twenty-fourth transistors T23 and T24 being commonly connected to the node. The third latch 5 is reset when the third reset signal ARST is enabled in a state in which the sensing node SO is at a high level. The reset third latch 5 is in a state in which the QA node QA is at a low level and the QA_N node QA_N is at a high level.

When the sensing node SO precharged to the level of the core voltage VCORE is connected to the bit line BL and a corresponding signal of the first to third set signals SSET, MSET, and ASET is enabled while the voltage level of the sensing node SO is gradually lowered, each of the first to third latches 3, 4, and 5 stores the level of the sensing node SO at the enabled time.

In an embodiment, the fourth latch 6 is configured as a cache latch that receives the values stored in the first to third latches 3, 4, and 5 through the sensing node SO and stores the received values under the control of the twenty-sixth to thirty-first transistors T26, T27, T28, T29, T30, and T31, and outputs the stored values as output data of the page buffer PB.

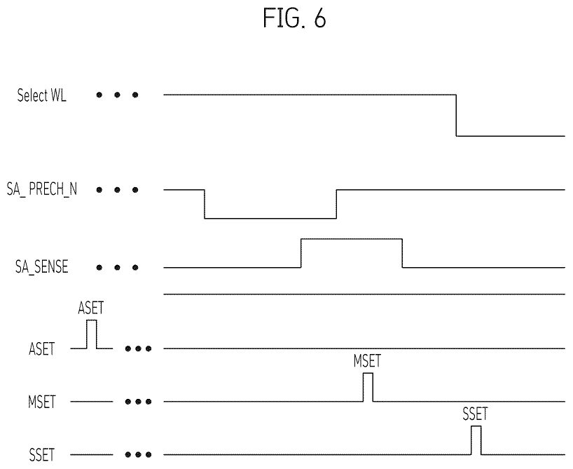

FIG. 6 is a timing diagram for describing an operation of a page buffer included in a semiconductor device in accordance with an embodiment of the present disclosure. In the operation of the page buffer, it is assumed that a memory cell on which a read operation is performed is a memory cell connected to the Nth word line, and an adjacent memory cell is a memory cell connected to the N+1^{th} word line. It is also assumed that the N+1^{th} word line is a word line to which during a program operation, memory cells to be programmed after the Nth word line are connected.

In an embodiment, the first to third latches 3, 4, and 5 all sense the voltage level of the sensing node SO in a reset state. Accordingly, the first to third latches 3, 4, and 5 are all in a reset state.

Referring to FIGS. 5 and 6, the N+1^{th} word line is driven, and the bit line BL and the sensing node SO are electrically connected by the connection circuit 1. In such a case, by enabling the third set signal ASET, the memory cell connected to the N+1^{th} word line is sensed through the bit line BL and stored in the third latch 5.

Subsequently, when the Nth word line Select WL is driven and the bit line select signal SELBL, the page buffer sensing signal PB_SENSE, and the sensing node sensing signal SA_SENSE are all enabled in a state in which the precharge signal SA_PRECH_N is enabled, the bit line BL and the precharged sensing node SO are electrically connected.

Subsequently, by enabling the second set signal MSET, the voltage level of the sensing node SO is stored in the second latch 4. Subsequently, by enabling the first set signal SSET, the voltage level of the sensing node SO is stored in the first latch 3. Accordingly, the first latch 3 latches the voltage level of the sensing node SO when the time duration during which the voltage level of the sensing node SO has changed is longer than in the second latch 4. That is, the first latch 3 stores a value corresponding to data sensed using the second read voltage Vread2 in FIG. 4. In addition, the second latch 4 stores a value corresponding to data sensed using the first read voltage Vread1 in FIG. 4.

As a result, the third latch 5 stores data of the memory cell connected to the N+1^{th} word line. In addition, the first and second latches 3 and 4 each store data of the memory cell connected to the Nth word line. In such a case, the sensing times of the first and second latches 3 and 4 are different from each other.

An operation, in which data is stored in each of the first to third latches 3, 4, and 5 and then the data stored in the first and second latches 3 and 4 is maintained or reset according to a value stored in the third latch 5, that is, the data, is described as follows.

In an embodiment, the sensing node SO is precharged to the core voltage VCORE, that is, a high level.

In an embodiment, the fourth transmission signal TRAN4 is enabled. When the fourth transmission signal TRAN4 is enabled, the voltage level of the sensing node SO is changed according to the voltage level of the QA node QA of the third latch 5. For example, when the level of the QA node QA is a high level, the level of the sensing node SO is changed to a low level. On the other hand, when the level of the QA node QA is a low level, the level of the sensing node SO is maintained at a high level.

Subsequently, the first set signal SSET is enabled. When the first set signal SSET is enabled, the QS_N node QS_N of the first latch 3 is changed according to the level of the sensing node SO. For example, when the level of the sensing node SO is a high level, the level of the QS_N node QS_N becomes a high level. In such a case, the level of the QS node QS becomes a low level. On the other hand, when the level of the sensing node SO is a low level, the level of the QS_N node QS_N is maintained.

As a result, the value stored in the first latch 3 is maintained or changed according to the value stored in the third latch 5. When the value stored in the first latch 3 is changed, it is the same as in a reset state.

Subsequently, the fifth transmission signal TRAN5 is enabled. When the fifth transmission signal TRAN5 is enabled, the voltage level of the sensing node SO is changed according to the voltage level of the QA_N node QA_N of the third latch 5. For example, when the level of the QA_N node QA_N is a high level, the level of the sensing node SO is changed to a low level. On the other hand, when the level of the QA_N node QA_N is a low level, the level of the sensing node SO is maintained at a high level.

Subsequently, the second set signal MSET is enabled. When the second set signal MSET is enabled, the QM_N node QM_N of the second latch 4 is changed according to the level of the sensing node SO. For example, when the level of the sensing node SO is a high level, the level of the QM_N node QM_N becomes a high level. In such a case, the level of the QM node QM becomes a low level. On the other hand, when the level of the sensing node SO is a low level, the level of the QM_N node QM_N is maintained.

As a result, the value stored in the second latch 4 is maintained or changed depending on the value stored in the third latch 5. In such a case, when the value stored in the second latch 4 is changed, it is the same as in a reset state.

Accordingly, when the value stored in the third latch 5 (on the basis of the QA node QA) is at a high level, the value stored in the first latch 3 is maintained, and the value stored in the second latch 4 is the same as the reset state. On the other hand, when the value stored in the third latch 5 (on the basis of the QA node QA) is at a low level, the value stored in the first latch 3 is the same as in a reset state, and the value stored in the second latch 4 is maintained.

Subsequently, the values stored in the first and second latches 3 and 4 are transmitted to the fifth latch 6, that is, transmitted to the cache latch 6, and are output to the outside of the page buffer PB.

As a result, the page buffer PB in accordance with an embodiment of the present disclosure stores two pieces of data by latching a target memory cell at different sensing times during a read operation, and outputs one of the two pieces of data sensed at different times to the outside according to data of a memory cell adjacent to the target memory cell.

Accordingly, the speed of the read operation described with reference to FIG. 5 is higher than the speed of the read operation in accordance with an embodiment of the present disclosure in which two sensing operations are performed by changing the level of the read voltage described in FIG. 4 and one of the results of the two sensing operations is output according to data sensed from the N+1^{th} word line.

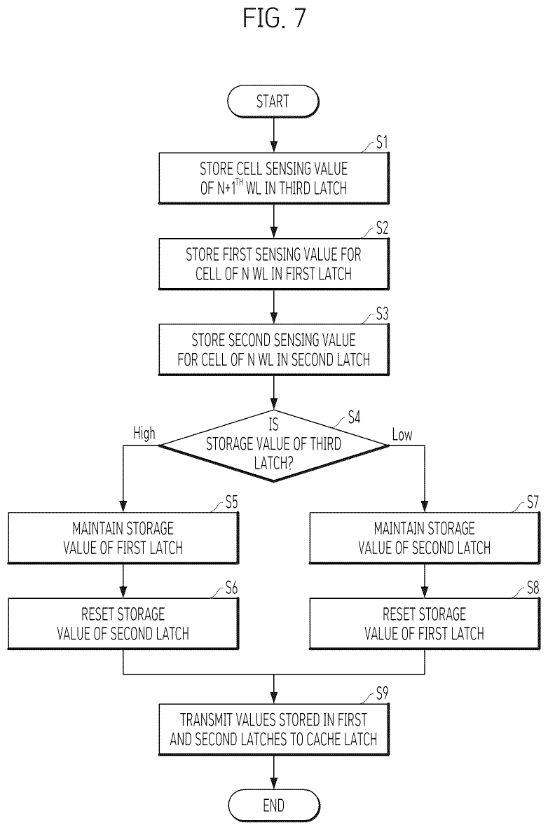

FIG. 7 is a flowchart for describing an operating method of a page buffer included in a semiconductor device in accordance with an embodiment of the present disclosure.

Referring to FIG. 7, the operating method includes a first storage operation S1, a second storage operation S2, a third storage operation S3, a selection operation S4, a first maintaining operation S5, a first reset operation S6, a second maintaining operation S7, a second reset operation S8, and a transmission operation S9.

In an embodiment, the first storage operation S1 is an operation of storing, in the third latch 5, a sensing value of a memory cell selected according to the driving of the N+1^{th} word line.

In an embodiment, the second storage operation S2 is an operation of storing, in the second latch 4, a sensing value of a memory cell selected according to the driving of the Nth word line.

In an embodiment, the third storage operation S3 is an operation of storing, in the first latch 3, a sensing value of a memory cell selected according to the driving of the Nth word line. In such a case, the sensing time of the second storage operation S2 occurs earlier than the sensing time of the third storage operation S3.

In an embodiment, the selection operation S4 is an operation of maintaining or resetting the values stored in the first and second latches 3 and 4 according to the value stored in the third latch 5.

When the value stored in the third latch 5 is high, the first maintaining operation S5 and the first reset operation S6 are sequentially performed.

When the value stored in the third latch 5 is low, the second maintaining operation S7 and the second reset operation S8 are sequentially performed.

In an embodiment, the first maintaining operation S5 is an operation of maintaining the value stored in the first latch 3.

In an embodiment, the first reset operation S6 is an operation of resetting the value stored in the second latch 4.

In an embodiment, the second maintaining operation S7 is an operation of maintaining the value stored in the second latch 4.

In an embodiment, the second reset operation S8 is an operation of resetting the value stored in the first latch 3.

In an embodiment, the transmission operation S9 is an operation of transmitting the values stored in the first and second latches 3 and 4 to the fourth latch 6, that is, the cache latch.

Although some embodiments according to the technical idea of the present disclosure have been described above with reference to the accompanying drawings, the present disclosure is not limited to these embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. An operating method of a semiconductor device, the method comprising:
receiving a read command;
sensing a memory cell adjacent to a target memory cell of the read command;
sensing the target memory cell at a first sensing time;
sensing the target memory cell at a second sensing time; and
outputting, as data, a value sensed at the first sensing time or a value sensed at the second sensing time on the basis of a sensing value of the memory cell adjacent to the target memory cell.

2. The operating method of a semiconductor device of claim 1, wherein the first sensing and the second sensing of the target memory cell occur at different times.

3. The operating method of a semiconductor device of claim 2, wherein the first sensing time is different from the second sensing time in an amount of time elapsed from precharging the sensing node.

4. The operating method of a semiconductor device of claim 2, wherein the sensing node is electrically connected to a bit line during a read operation, and a plurality of latches are sequentially connected to the sensing node.

5. The operating method of a semiconductor device of claim 1, wherein the memory cell adjacent to the target memory cell and the target memory cell are electrically connected to a same bit line but are electrically connected to different word lines.

6. The operating method of a semiconductor device of claim 1, wherein, when a plurality of word lines are sequentially driven and programmed, the memory cell adjacent to the target memory cell is programmed immediately after the target memory cell is programmed.

7. An operating method of a page buffer, the method comprising:
connecting a sensing node of the page buffer to a bit line during a read operation;
sensing the sensing node by driving a first word line and storing a first sensed value in a first latch;
sensing the sensing node at a first time by driving a second word line and storing a second sensed value in a second latch;
sensing the sensing node at a second time after the storing of the sensed value in the first latch and storing a third sensed value in a third latch; and
outputting the second sensed value stored in the second latch or the third sensed value stored in the third latch as data on the basis of the first sensed value stored in the first latch.

8. The operating method of a page buffer of claim 7, wherein the first, second, and third latches are each used to sense a voltage value of the sensing node.

9. The operating method of a page buffer of claim 7, wherein the first word line is driven after the second word line is driven during a program operation.

10. The operating method of a page buffer of claim 7, wherein the first time occurs before the second time.

11. A page buffer comprising:
a first latch that senses a first voltage value of a sensing node formed by a first word line;
a second latch that senses a second voltage value of the sensing node formed by a second word line adjacent to the first word line; and
a third latch that senses a third voltage value of the sensing node formed by the second word line, wherein the third voltage value is sensed at a different time from when the second voltage value is sensed.

12. The page buffer of claim 11, wherein the second voltage value sensed by the second latch or the third voltage value sensed by the third latch is selected and output according to the first voltage value sensed by the first latch.

13. The page buffer of claim 11, wherein the third latch senses the third voltage value after the second latch senses the second voltage value.
